(19) United States
(12) Patent Application Publication
(10) Pub. No.: US 2025/0317108 A1
(43) Pub. Date: Oct. 9, 2025

(54) System and Process for Automatic Analysis and Optimization of Amplifiers

(71) Applicant: Comcast Cable Communications, LLC, Philadelphia, PA (US)

(72) Inventors: Lawrence Wolcott, JR., Denver, CO (US); John Chrostowski, Warrington, PA (US); Joseph Mitchell, Ridgefield, WA (US); Michael O'Dell, Vienna, OH (US); Matthew Wichman, Bothell, WA (US); Daniel Rice, Boulder, CO (US); Maher Harb, Wynnewood, PA (US)

(21) Appl. No.: 18/625,597

(22) Filed: Apr. 3, 2024

(51) Int. Cl. H03F 3/19

(52) U.S. Cl. CPC H03F 3/19; H03F 2200/451

(57) ABSTRACT

Systems, apparatuses, and methods are described for analyzing and optimizing an amplifier and/or a system of amplifiers based on a noise profile of the amplifier and/or the system of amplifiers. Changes in output power and noise profile of the amplifier and/or the amplifier system may be measured and analyzed, for example, by changing the input power to the amplifier system. Based on the changes to the noise levels and/or output power, the behavior of the amplifier and/or amplifier system may be remotely characterized and used to optimize the amplifier system.

### BACKGROUND

Amplifiers and amplifier systems are common in modern technologies. Modern communication systems may have millions of amplifiers embedded into various portions of the communication systems. Any components, from signal origination to endpoint devices and/or terminal devices may be configured with broadband and/or wideband capture that provides spectrum analysis. Methods and systems for utilizing spectrum analysis and other data to monitor and tune amplifiers are discussed in the disclosure.

### SUMMARY

The following summary presents a simplified summary of certain features. The summary is not an extensive overview and is not intended to identify key or critical elements.

Systems, apparatuses, and methods are described for remotely analyzing and optimizing systems of one or more amplifiers. An endpoint device and/or a terminal device (e.g., a consumer premises equipment (CPE)) may be configured with spectrum analyzer functionality. The spectrum analyzer functionality measures a spectrum of a band of frequencies and may provide details on the strength of a radio frequency (RF) signal over the band of frequencies. The spectrum analyzer functionality may also be used to determine noise characteristics of the band of frequencies. By automatically adjusting input power to an amplifier system and measuring the resulting change in the spectrum, changes in signal power and/or noise power may be determined. Changes to the signal power and/or noise power based on changes to input power may be used to remotely analyze characteristics (e.g., the linearity) of the amplifier system. Automatically analyzing amplifier system characteristics, limits or eliminates any measurement biases due to experience, equipment, and/or interpretation that may be introduced by a technician. Moreover, by automatically analyzing an amplifier system a history of the amplifier system may be generated and/or trends in the amplifier system's characteristics discovered. Human induced errors may be reduced and/or network performance may be improved, for example, by automating analysis and adjustments to an amplifier configuration for setup and/or maintenance because of network changes.

These and other features and advantages are described in greater detail below.

### BRIEF DESCRIPTION OF THE DRAWINGS

Some features are shown by way of example, and not by limitation, in the accompanying drawings. In the drawings, like numerals reference similar elements.

FIG. 1 shows an example communication network.

FIG. 2 shows hardware elements of a computing device.

FIGS. 3A and 3B show an example of a method to determine distortion noise (dn) of an amplifier system.

FIGS. 4A and 4B show example noise power ratio (NPR) curves for an amplifier system.

FIG. 5A is a flow chart showing an example method for automatic analysis and optimization of the linearity of an amplifier system.

FIG. 5B is a flow chart showing an example method for automatic analysis and optimization of the internal gain control circuits of an amplifier system by separately manipulating the gain control pilots.

FIG. 6A shows an example of manual input power manipulation and analysis of an amplifier system.

FIG. 6B shows an example of two endpoint device and/or a terminal device spectra.

FIG. 6C shows an example of determined positions on a noise power ratio (NPR) curve.

FIG. 7A shows an example of automated input power manipulation and analysis of an amplifier system.

FIG. 7B shows an example of a first endpoint device and/or a terminal device spectrum of a first amplifier system

FIG. 7C shows an example of a second endpoint device and/or a terminal device spectrum of a second amplifier system.

FIG. 8A shows an example of automated input power manipulation and analysis of an amplifier system.

FIG. 8B shows an example of a first endpoint device and/or a terminal device spectrum of a first amplifier system.

FIG. 8C shows an example of a second endpoint device and/or a terminal device spectrum of a second amplifier system.

### DETAILED DESCRIPTION

The accompanying drawings, which form a part hereof, show examples of the disclosure. It is to be understood that the examples shown in the drawings and/or discussed herein are non-exclusive and that there are other examples of how the disclosure may be practiced.

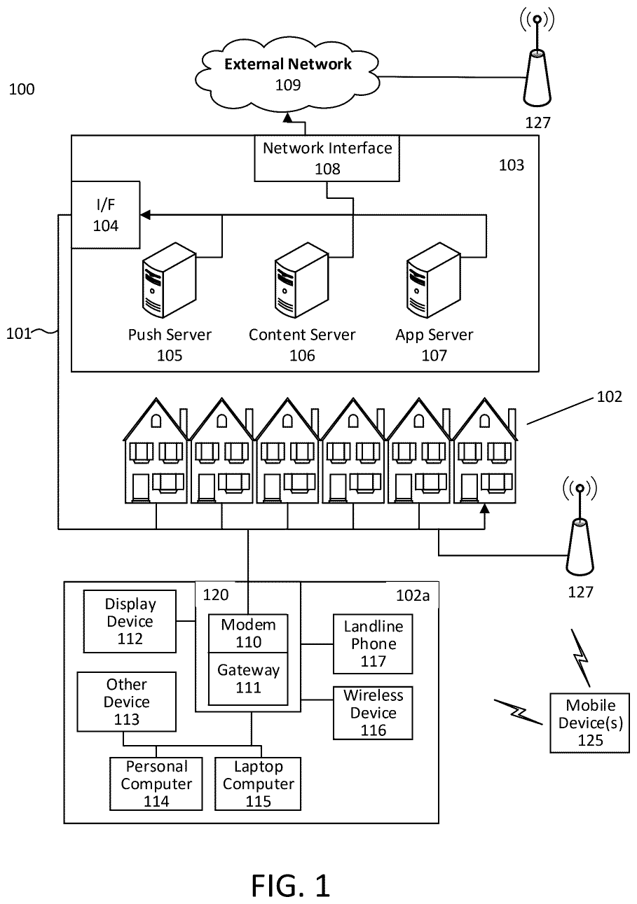

FIG. 1 shows an example communication network 100 in which features described herein may be implemented. The communication network 100 may comprise one or more information distribution networks of any type, such as, without limitation, a telephone network, a wireless network (e.g., an LTE network, a 5G network, a WiFi IEEE 802.11 network, a WiMAX network, a satellite network, and/or any other network for wireless communication), an optical fiber network, a coaxial cable network, and/or a hybrid fiber/coax distribution network. The communication network 100 may use a series of interconnected communication links 101 (e.g., coaxial cables, optical fibers, wireless links, etc.) to connect multiple premises 102 (e.g., businesses, homes, consumer dwellings, train stations, airports, etc.) to a local office 103 (e.g., a headend). The local office 103 may send downstream information signals and receive upstream information signals via the communication links 101. Each of the premises 102, terminal locations, and/or receiver locations may comprise devices, described below, to receive, send, and/or otherwise process those signals and information contained therein.

The communication links 101 may originate from the local office 103 and may comprise components not shown, such as splitters, filters, amplifiers, etc., to help convey signals clearly. The communication links 101 may be coupled to one or more wireless access points 127 configured to communicate with one or more mobile devices 125 via one or more wireless networks. The mobile devices 125 may comprise smart phones, tablets or laptop computers with wireless transceivers, tablets or laptop computers communicatively coupled to other devices with wireless transceivers, and/or any other type of device configured to communicate via a wireless network.

The local office 103 may comprise an interface 104. The interface 104 may comprise one or more computing devices configured to send information downstream to, and to receive information upstream from, devices communicating with the local office 103 via the communications links 101. The interface 104 may be configured to manage communications among those devices, to manage communications between those devices and backend devices such as servers 105-107, and/or to manage communications between those devices and one or more external networks 109. The interface 104 may, for example, comprise one or more routers, one or more base stations, one or more optical line terminals (OLTs), one or more termination systems (e.g., a modular cable modem termination system (M-CMTS) or an integrated cable modem termination system (I-CMTS)), one or more digital subscriber line access modules (DSLAMs), and/or any other computing device(s). The local office 103 may comprise one or more network interfaces 108 that comprise circuitry needed to communicate via the external networks 109. The external networks 109 may comprise networks of Internet devices, telephone networks, wireless networks, wired networks, fiber optic networks, and/or any other desired network. The local office 103 may also or alternatively communicate with the mobile devices 125 via the interface 108 and one or more of the external networks 109, e.g., via one or more of the wireless access points 127.

The push notification server 105 may be configured to generate push notifications to deliver information to devices in the premises 102 and/or to the mobile devices 125. The content server 106 may be configured to provide content to devices in the premises 102 and/or to the mobile devices 125. This content may comprise, for example, video, audio, text, web pages, images, files, etc. The content server 106 (or, alternatively, an authentication server) may comprise software to validate user identities and entitlements, to locate and retrieve requested content, and/or to initiate delivery (e.g., streaming) of the content. The application server 107 may be configured to offer any desired service. For example, an application server may be responsible for collecting, and generating a download of, information for electronic program guide listings. Another application server may be responsible for monitoring user viewing habits and collecting information from that monitoring for use in selecting advertisements. Yet another application server may be responsible for formatting and inserting advertisements in a video stream being transmitted to devices in the premises 102 and/or to the mobile devices 125. The local office 103 may comprise additional servers, additional push, content, and/or application servers, and/or other types of servers. Although shown separately, the push server 105, the content server 106, the application server 107, and/or other server(s) may be combined. The servers 105, 106, 107, and/or other servers, may be computing devices and may comprise memory storing data and also storing computer executable instructions that, when executed by one or more processors, cause the server(s) to perform steps described herein.

An example premises 102a may comprise an interface 120. The interface 120 may comprise circuitry used to communicate via the communication links 101. The interface 120 may comprise a modem 110, which may comprise transmitters and receivers used to communicate via the communication links 101 with the local office 103. The modem 110 may comprise, for example, a coaxial cable modem (for coaxial cable lines of the communication links 101), a fiber interface node (for fiber optic lines of the communication links 101), twisted-pair telephone modem, a wireless transceiver, and/or any other desired modem device. One modem is shown in FIG. 1, but a plurality of modems operating in parallel may be implemented within the interface 120. The interface 120 may comprise a gateway 111. The modem 110 may be connected to, or be a part of, the gateway 111. The gateway 111 may be a computing device that communicates with the modem(s) 110 to allow one or more other devices in the premises 102a to communicate with the local office 103 and/or with other devices beyond the local office 103 (e.g., via the local office 103 and the external network(s) 109). The gateway 111 may comprise a set-top box (STB), digital video recorder (DVR), a digital transport adapter (DTA), a computer server, and/or any other desired computing device.

The gateway 111 may also comprise one or more local network interfaces to communicate, via one or more local networks, with devices in the premises 102a. Such devices may comprise, e.g., customer premises equipment (CPE), display devices 112 (e.g., televisions), other devices 113 (e.g., a DVR or STB), personal computers 114, laptop computers 115, wireless devices 116 (e.g., wireless routers, wireless laptops, notebooks, tablets and netbooks, cordless phones (e.g., Digital Enhanced Cordless Telephone-DECT phones), mobile phones, mobile televisions, personal digital assistants (PDA)), landline phones 117 (e.g., Voice over Internet Protocol VoIP phones), and any other desired devices. Example types of local networks comprise Multimedia Over Coax Alliance (MoCA) networks, Ethernet networks, networks communicating via Universal Serial Bus (USB) interfaces, wireless networks (e.g., IEEE 802.11, IEEE 802.15, Bluetooth), networks communicating via in-premises power lines, and others. The lines connecting the interface 120 with the other devices in the premises 102a may represent wired or wireless connections, as may be appropriate for the type of local network used. One or more of the devices at the premises 102a may be configured to provide wireless communications channels (e.g., IEEE 802.11 channels) to communicate with one or more of the mobile devices 125, which may be on-or off-premises.

The mobile devices 125, one or more of the devices in the premises 102a, and/or other devices may receive, store, output, and/or otherwise use assets. An asset may comprise a video, a game, one or more images, software, audio, text, webpage(s), and/or other content.

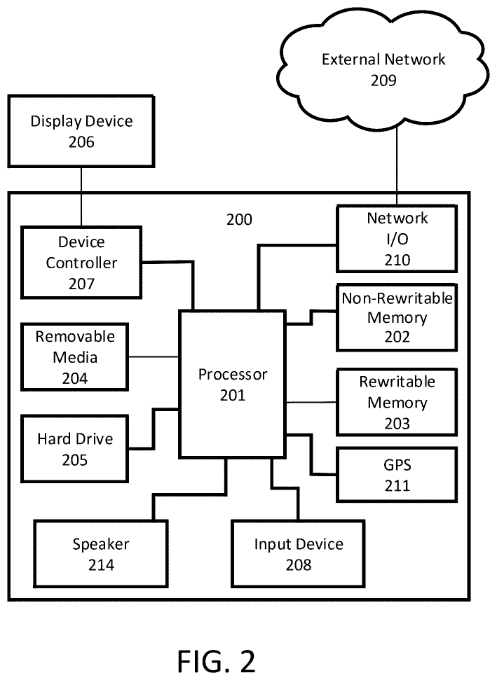

FIG. 2 shows hardware elements of a computing device 200 that may be used to implement any of the computing devices shown in FIG. 1 (e.g., the mobile devices 125, any of the devices shown in the premises 102a, any of the devices shown in the local office 103, any of the wireless access points 127, any devices with the external network 109) and any other computing devices discussed herein (e.g., customer premises equipment (CPE)). The computing device 200 may comprise one or more processors 201, which may execute instructions of a computer program to perform any of the functions described herein. The instructions may be stored in a non-rewritable memory 202 such as a read-only memory (ROM), a rewritable memory 203 such as random access memory (RAM) and/or flash memory, removable media 204 (e.g., a USB drive, a compact disk (CD), a digital versatile disk (DVD)), and/or in any other type of computer-readable storage medium or memory. Instructions may also be stored in an attached (or internal) hard drive 205 or other types of storage media. The computing device 200 may comprise one or more output devices, such as a display device 206 (e.g., an external television and/or other external or internal display device) and a speaker 214, and may comprise one or more output device controllers 207, such as a video processor or a controller for an infra-red or BLUETOOTH transceiver. One or more user input devices 208 may comprise a remote control, a keyboard, a mouse, a touch screen (which may be integrated with the display device 206), microphone, etc. The computing device 200 may also comprise one or more network interfaces, such as a network input/output (I/O) interface 210 (e.g., a network card) to communicate with an external network 209. The network I/O interface 210 may be a wired interface (e.g., electrical, RF (via coax), optical (via fiber)), a wireless interface, or a combination of the two. The network I/O interface 210 may comprise a modem configured to communicate via the external network 209. The external network 209 may comprise the communication links 101 discussed above, the external network 109, an in-home network, a network provider's wireless, coaxial, fiber, or hybrid fiber/coaxial distribution system (e.g., a DOCSIS network), or any other desired network. The computing device 200 may comprise a location-detecting device, such as a global positioning system (GPS) microprocessor 211, which may be configured to receive and process global positioning signals and determine, with possible assistance from an external server and antenna, a geographic position of the computing device 200.

Although FIG. 2 shows an example hardware configuration, one or more of the elements of the computing device 200 may be implemented as software or a combination of hardware and software. Modifications may be made to add, remove, combine, divide, etc. components of the computing device 200. Additionally, the elements shown in FIG. 2 may be implemented using basic computing devices and components that have been configured to perform operations such as are described herein. For example, a memory of the computing device 200 may store computer-executable instructions that, when executed by the processor 201 and/or one or more other processors of the computing device 200, cause the computing device 200 to perform one, some, or all of the operations described herein. Such memory and processor(s) may also or alternatively be implemented through one or more Integrated Circuits (ICs). An IC may be, for example, a microprocessor that accesses programming instructions or other data stored in a ROM and/or hardwired into the IC. For example, an IC may comprise an Application Specific Integrated Circuit (ASIC) having gates and/or other logic dedicated to the calculations and other operations described herein. An IC may perform some operations based on execution of programming instructions read from ROM or RAM, with other operations hardwired into gates or other logic. Further, an IC may be configured to output image data to a display buffer.

In a system comprising multiple communication channels (e.g., a network 109, 101, etc.), all of the channels may be affected by a noise floor related to a transmitter and/or a receiver, but each channel may also be affected by intermodulation and/or harmonics within the channel as well as intermodulation noise between the other channels of the system. A noise power ratio (NPR) may be used to interpret system performance. A NPR measurement may comprise manipulating input power to the communication system. For an NPR measurement of a system, typically, an output power of a channel under test is measured using a noise generator spectrum applied with a notch filter applied at the frequency of the channel under test, where a notch filter is a band-stop type filter that filters frequencies within a specific frequency range while allowing all other frequencies to pass with low loss. The ratio of the output power of the channel, with the noise generator spectrum applied (e.g., P₀), to the output power of the channel, with the noise generator spectrum notched (e.g., P_{f}), is the NPR (e.g., P₀/P_{f}). The NPR may be considered a measurement of the noise introduced into a channel by using the other channels in the system.

NPR measurements are typically done in a laboratory environment but may be extrapolated from manual operations and measurements that may be used in the field. Total composite power (TCP) (e.g., the area under a power or power level vs frequency plot) may be determined from measurements using a spectrum analyzer. Relative channel power levels may be given to a technician, and the technician may balance an amplifier system, for example, based on measuring input and output channel powers to determine TCP within gain stages of the amplifier system. Technicians may experience variations in measured TCP using this method, however, because the method relies on a technician's training and experience which varies between technicians. A technician, moreover, may also be required to setup a measurement, perform the measurement, and/or interpret the measurement. Typically, the setup and maintenance of amplifiers is a manual process. Tools such as signal level meters are available to assist technicians, but they often produce readings that require human interpretation. Consequently, technicians need to physically adjust the amplifier settings, retest them, and/or repeat the process until the technician believes the optimal configuration has been achieved. The optimal configuration may often not always be optimal because of human error, and/or because of network changes, from changes in temperature and/or induced by faults and any subsequent maintenance activities to repair the faults, all resulting in reduced capacity or inconsistent customer experience.

A method based on a noise measurements (e.g., signal-to-noise raise (SNR), modulation error ratio (MER), carrier-to-noise (CNR), etc.) may be used to automate setup and ongoing maintenance of radio frequency (RF) amplifier systems within communication systems, including wireless communication. Moreover, noise measurements may be used to determine where on a noise power ratio (NPR) curve an amplifier and/or system of amplifiers may sit. An amplifier and/or a system of amplifiers may be tested and analyzed based on the noise profile that the amplifier and/or the system of amplifiers may produce. The noise may be measured at the amplifier and/or system of amplifiers or downstream of the amplifier and/or amplifier system. Characteristics of the amplifier and/or the system of amplifiers may be determined, for example, by measuring the noise of the amplifier and/or system of amplifiers rather than signal characteristics.

TCP may be manipulated to an input of an amplifier system and the amplifier system evaluated based on the observed changes in spectrum. The amplifier system may comprise one or more amplifiers. The amplifier system may be configured within an amplifier assembly and/or embedded in amplifier circuits and/or modules within other systems (e.g., RF nodes, trays, shelfs, modems, etc.). Performance of the amplifier system may be determined based on a distortion noise (dn) measurement of a spectrum. The spectrum may be determined, for example, using full band capture (FBC) capabilities of an endpoint device and/or terminal device (e.g., customer premises equipment (CPE), the modem 110 of FIG. 1, etc.).

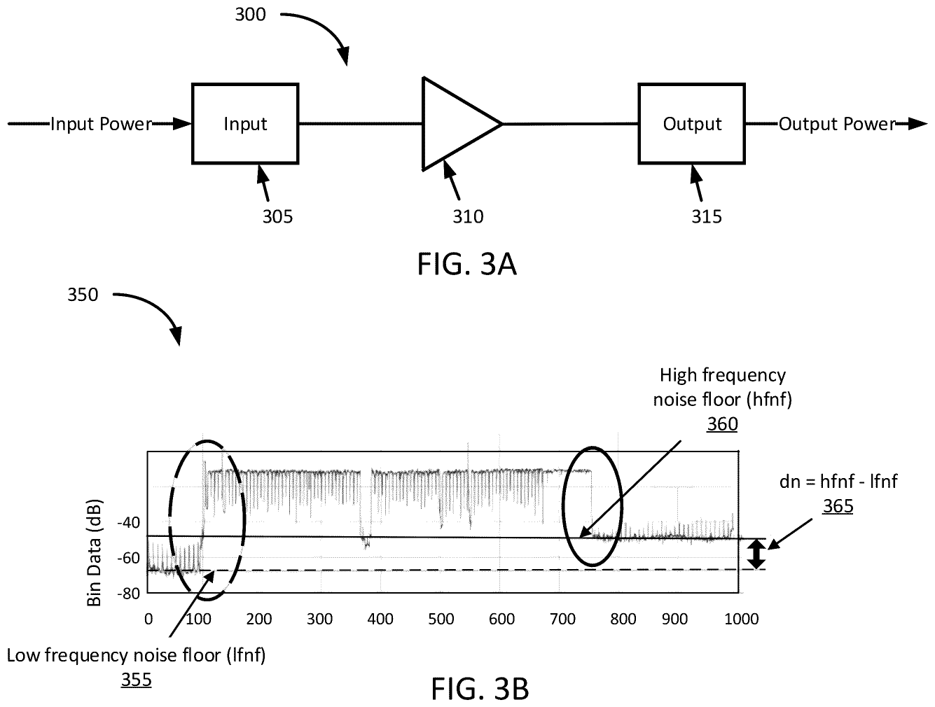

FIGS. 3A and 3B show an example of a method to determine distortion noise (dn) of an amplifier system. FIG. 3A shows an example of an amplifier system 300. The amplifier system 300 may be comprised by an endpoint device and/or terminal device (e.g., a CPE, the modem 110 of FIG. 1, etc.). The amplifier system 300 may comprise an input 305, one or more amplifiers 310, and an output 315. Measurements of the dn may comprise measuring input and/or output characteristics of the amplifier system 300. Measurements of input and/or output characteristics may comprise measuring input power and/or corresponding output power. Measurements of input and/or output characteristics may comprise calculating ratios of the signal and/or noise powers. Measurements of input and/or output characteristics may comprise determining one or more spectra.

Input power to an amplifier system 300 may be manipulated to stimulate and/or test linear functions of amplifier circuits. Input power may be changed, for example, based on programmatically manipulating transmitter power to existing channels. Input power may be changed, for example, based on programmatically adding power to a vacant and/or unused portion of a spectrum. Input power may be changed, for example, based on an automated or manual process. The manual process may comprise, for example, injecting power at the input 305 of an amplifier system 300, for example, using an external piece of hardware (e.g., a signal generator).

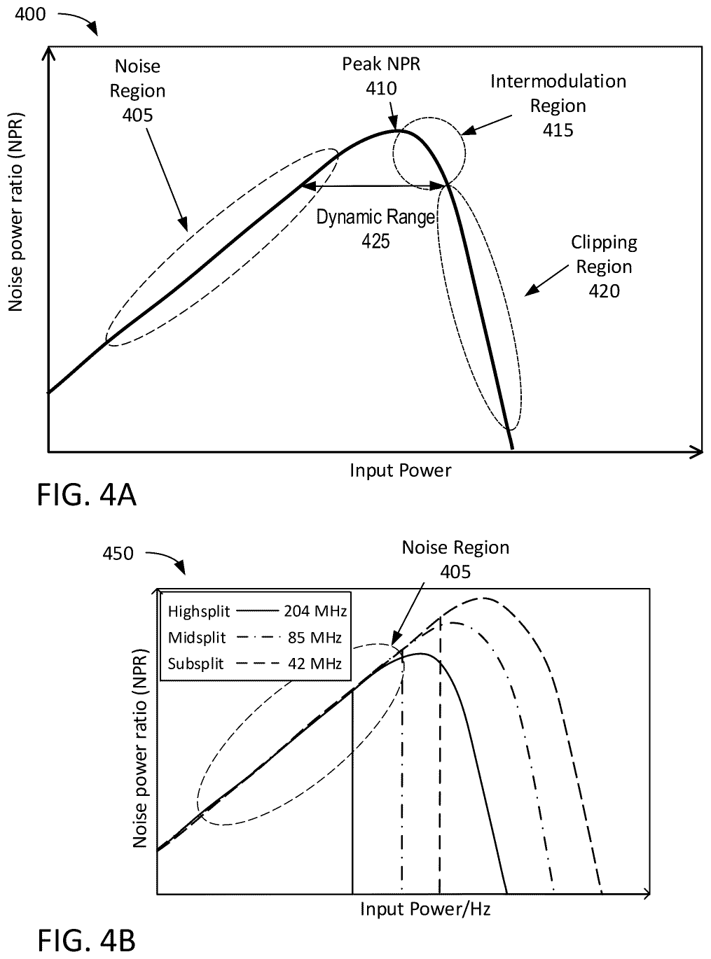

Characteristics of the amplifier system 300 may be determined, for example, by manipulating input power to the amplifier system 300 and determining changes in the input power, output power, and/or changes in ratios of signal and noise powers. FIG. 3B shows an example of a spectrum measurement 350 of an amplifier system 300. The spectrum may be acquired, for example, by using a spectrum analyzer and/or by using the FBC capabilities of an endpoint device and/or a terminal device (e.g., a CPE). The spectrum of the amplifier system 300 may be determined while in use, for example, using the FBC of the endpoint device and/or the terminal device (e.g., a CPE, the modem 110 of FIG. 1). A portion of the spectrum measurement 350 may comprise low frequencies, and a portion of the spectrum measurement 350 may comprise high frequencies. A dn 365 may be determined, for example, based on a difference between a low frequency noise floor (lfnf) 355 and a high frequency noise floor (hfnf) 360. The lfnf may be referenced to system noise, which may be outside the downstream bandwidth and may not be a part of a difference in noise because of a diplex filter. The noise floor may comprise the sum of substantially all noise in a measurement setup when there is no signal running through. The lfnf 355 may be determined from the noise floor of the low frequency portion of the spectrum measurement, and the hfnf 360 may be determined from the noise floor of the high frequency portion of the spectrum measurement. The lfnf 355 and/or the hfnf 360 may be, for example, an average and/or an adjusted average (e.g., a weighted average) of the respective floors. The noise floor may also be inferred or interpolated from a power vs an error ratio (e.g., a modulation error ratio (MER)). The dn may also be measured before and/or after an input power increase and/or decrease action and correlated with the high frequency portion of the spectrum changes to identify the effect of the input power change that may be based on the difference between an NPR curve and the different slopes of a noise region, an intermodulation region, and a clipping region as described herein in FIG. 4.

One or more dn 365 values may be determined to characterize an amplifier system 300. The one or more dn 365 values may be determined, for example, by manipulating the amplifier system 300 with one or more different input powers. The signal-to-noise ratio (SNR), the ratio of signal power to background noise power, may remain constant with changing input power, for example, if the amplifier system is in automatic gain control (AGC) state. A changing SNR may indicate, for example, non-linearity of the amplifier system 300, distortions in the amplifier system 300, and/or an amplifier system 300 in a constant gain state. A lfnf may not be a part of the dn because of a diplex filter.

FIGS. 4A and 4B show example NPR curves for an amplifier system. FIG. 4A shows an NPR curve 400 and its different features. An NPR curve 400 may show a number of features that may correspond to behavior exhibited by an amplifier system 300. The NPR curve 400 may comprise a noise region 405, an NPR peak 410, an intermodulation region 415, a clipping region 420, and a dynamic range region 425. The noise region 405 may demonstrate a nearly (e.g., substantially) linear increase in noise as input power is increased and may be dominated by thermal noise. The output power of a channel may increase as input power to the channel is increased, for example, if the amplifier system 300 is in the noise region 405. The SNR may increase as output power increases because the output signal increases while the noise may remain constant. The SNR may increase as output power increases, for example, if the amplifier system is constant gain because the output power would increase as input power increases. Additionally, an output power level may remain constant, for example, if the amplifier system 300 is in an automatic gain control (AGC) state because the AGC state may keep the output level substantially constant which, in turn, may keep the SNR substantially constant.

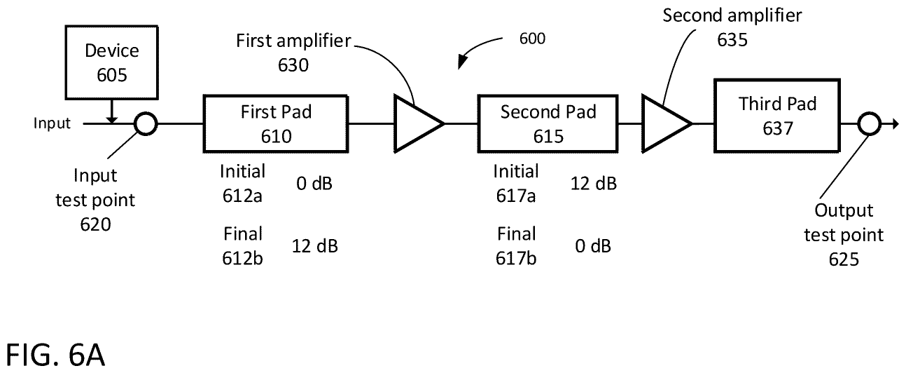

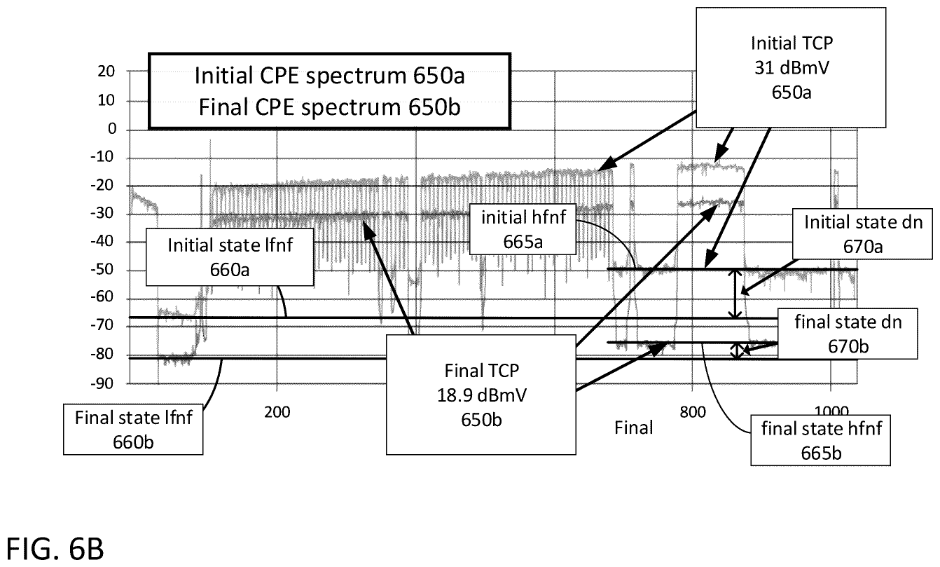

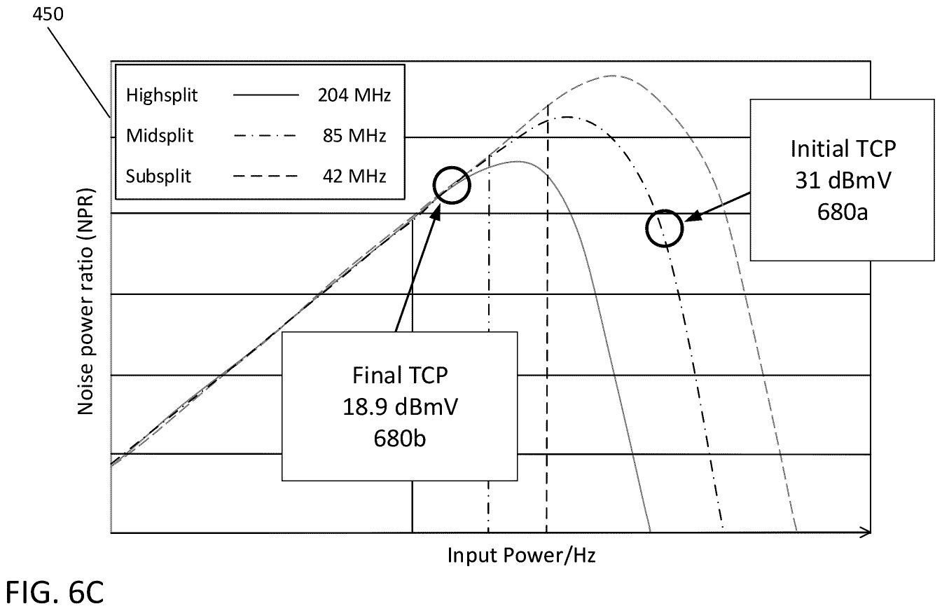

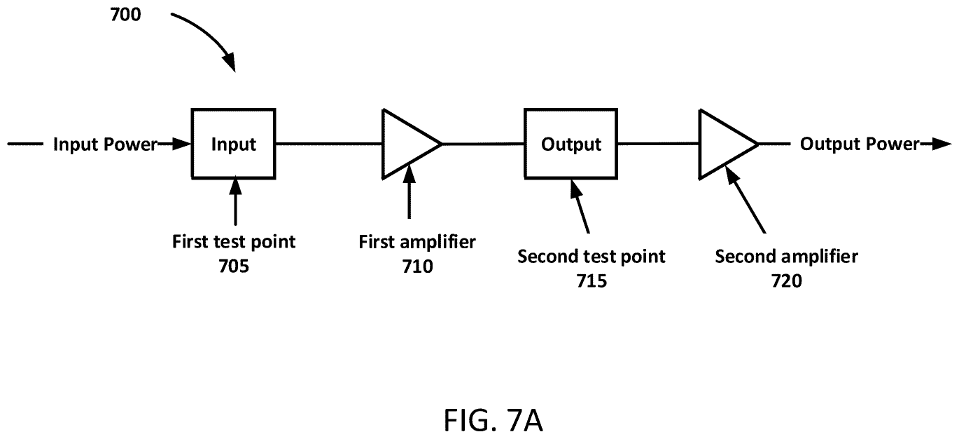

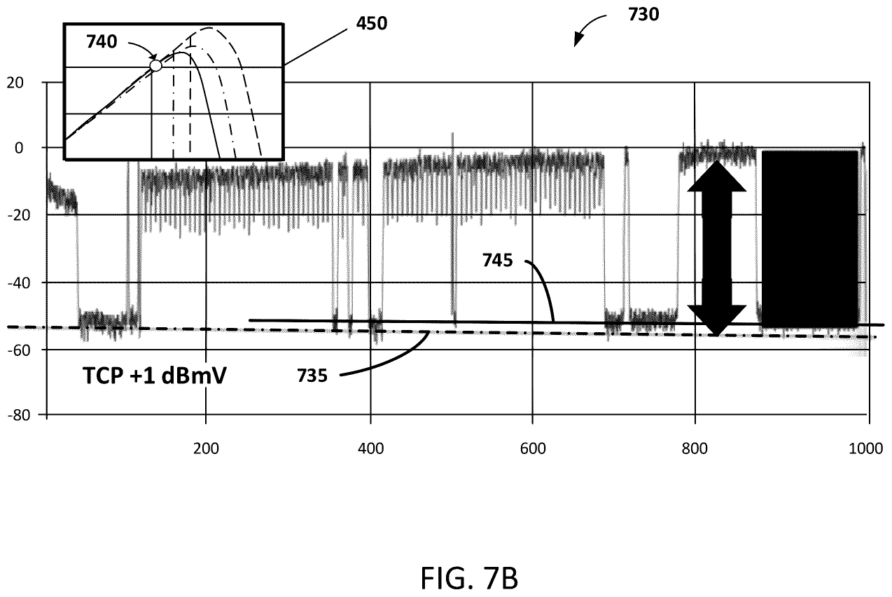

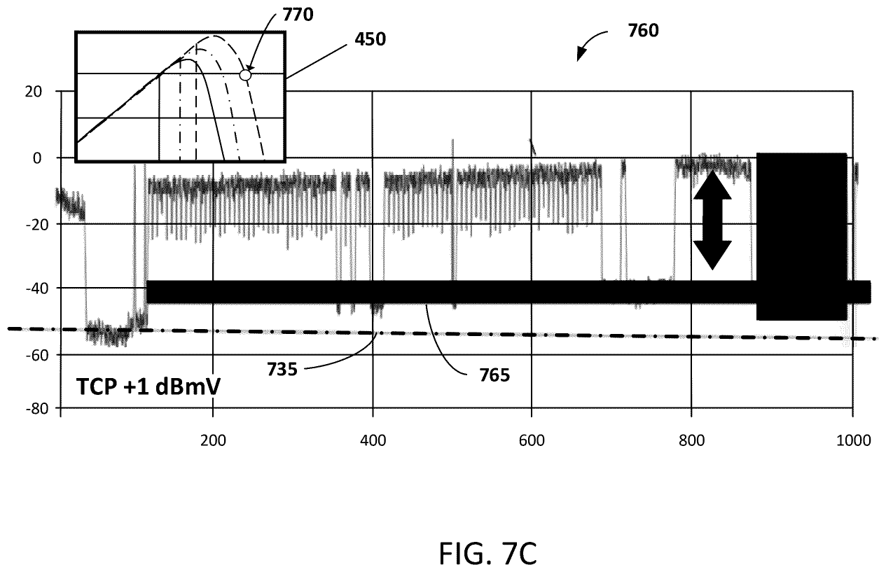

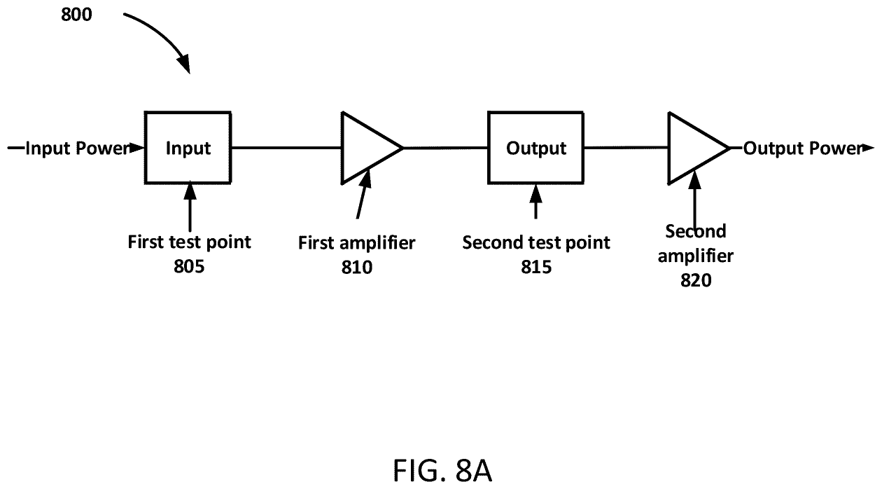

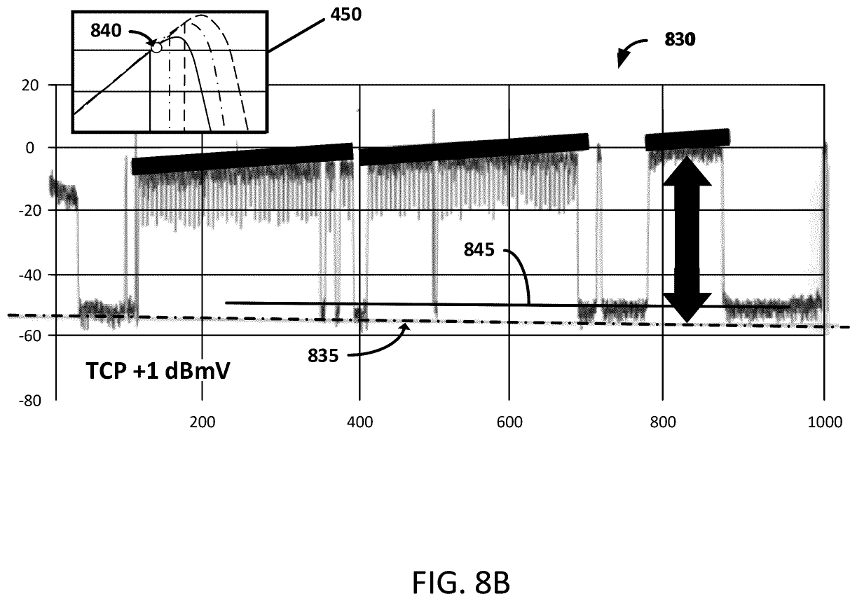

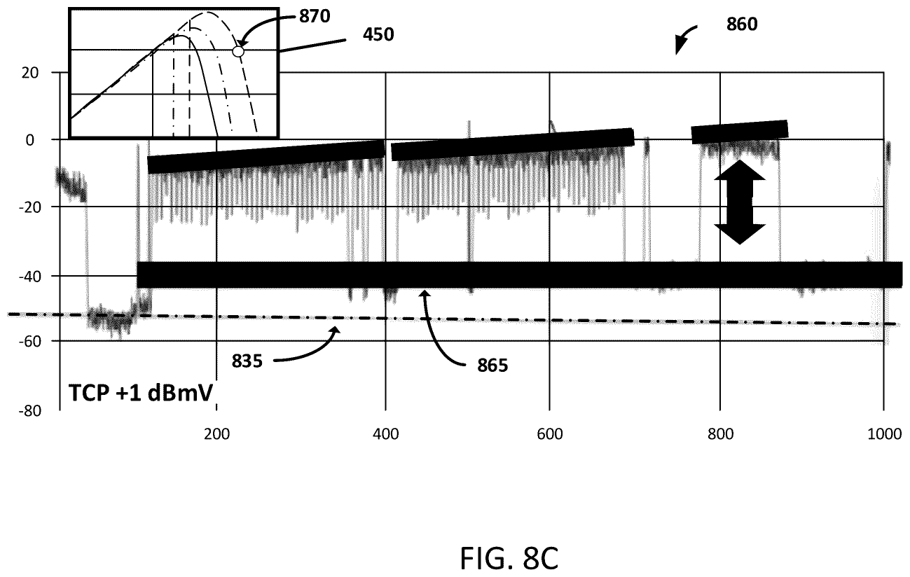

An intermodulation region 415 may comprise the peak NPR 410 and may comprise the region in which the noise in an amplifier system 300 (e.g., as described herein in FIG. 3A, FIG. 6A, FIG. 7A, and FIG. 8A) begins to be dominated (e.g., the predominate contributor to the noise) by properties other thermal noise. The peak NPR 410 is where the NPR curve 400 reaches its highest value and differentiates the regions of the NPR curve 400 where the NPR curve 400 is dominated by thermal noise and where the NPR curve 400 is dominated by intermodulation noise and/or distortion products. A clipping region 420 may lie to the right of the peak NPR 410 on the NPR curve 400. As TCP is increased in the clipping region 420, an amplifier system 300 may be substantially driven to saturation. Power in the clipping region 420 may be dominated by high order intermodulation noise and/or distortion products, and the NPR curve 400 may decrease rapidly with increasing input power. The dynamic range 425 region corresponds to the region where an amplifier system 300 may be optimally used.

Maintaining an amplifier in the intermodulation region 415 and near the peak NPR 410 may increase network capacity and/or performance because as the NPR is maximized the SNR at an interface 120 and/or 104 increases. App server 107 and push server 105 may comprise network management and configuration servers that may optimize the capacity via one or more systems. An operating power of an amplifier may be set below the peak NPR 410, for example, to prevent the amplifier from entering the intermodulation region 415 and/or clipping region 420 where performance degrades quickly because of the non-linearity of the system. A technician may manually set operating points below the peak NPR 410. A method of automating the setting the operating point of input power for maximum performance and capacity via software and remote automated management and configuration of all of the amplifier systems described in 101, 310, 600, 700, 800 collectively is described herein.

FIG. 4B shows an example of multiple normalized NPR curves for different frequency splits, where the normalization is based on frequency split (e.g., sub-split, mid-split, and high-split). By normalizing the curves, the noise regions 405 of the NPR curves substantially coincide.

Analysis of an amplifier system 300 (e.g., linearity of the amplifier system 300) may be performed by, for example, manipulating input power and observing the response of the output signal power and/or output noise. A person at a device comprising the amplifier system may initiate the analysis and optimization of the amplifier system. A server at a location different from the device comprising the amplifier system (e.g., a remote device) may initiate the analysis and optimization, for example, by sending an indication to the device to perform the analysis. Also, or alternatively, the device comprising the amplifier system may automatically perform the analysis, for example, based on a specific date and/or time, or based on a periodicity setting.

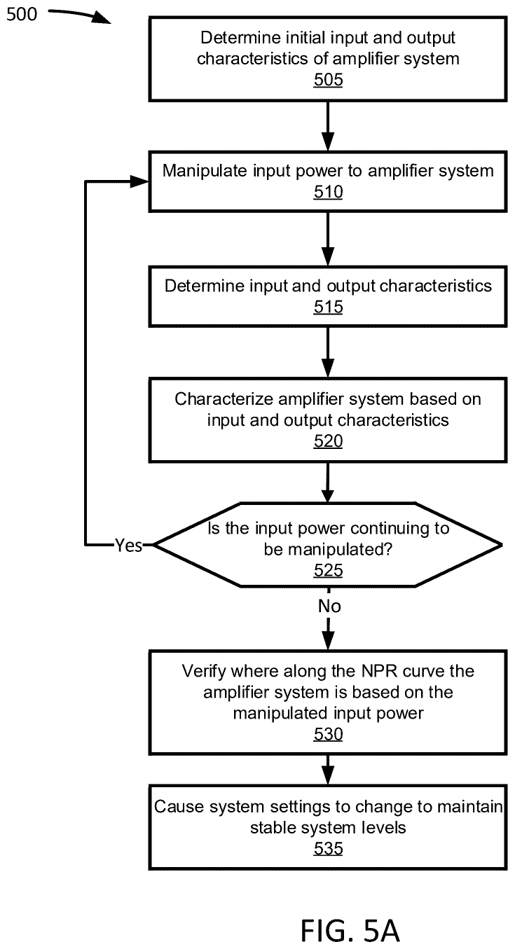

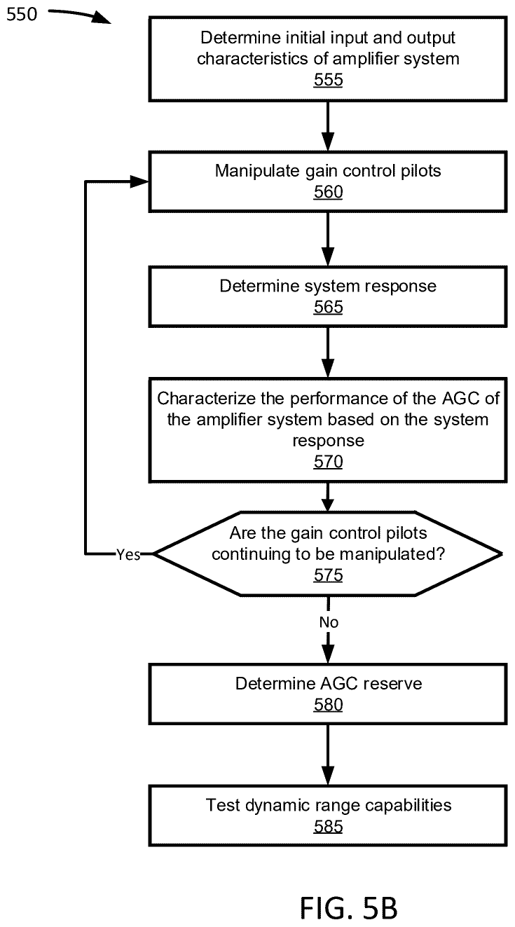

An amplifier and/or a system of amplifiers may be tested and analyzed, for example, based on a noise profile that is produced by the amplifier and/or the system of amplifiers rather than signal characteristics of the amplifier and/or the system of amplifiers. FIG. 5A is a flow chart showing an example method 500 for automatic analysis and optimization of an amplifier system 300. At step 505, initial characteristics of an amplifier system 300 may be measured. The initial characteristics may comprise input characteristics and/or output characteristics, and the input and/or output characteristics may comprise power values and/or noise values. The initial characteristics of the amplifier system 300 may be measured at amplifier system 300 using test points. Noise power may be measured using a combination of receive power and/or modulation error ratio (MER) or signal-to-noise ratio (SNR). Also, or alternatively, noise power may be measured as SNR or carrier-to-noise ratio (CNR). Initial characteristics may be determined using an endpoint device and/or terminal device (e.g., a customer premises equipment (CPE)).

At step 510 of the method 500, input power to the amplifier system 300 may be manipulated. The input power of the amplifier system 300 may be manipulated, for example, manually or automatically. The input power of the amplifier system 300 may be manipulated manually, for example, by injecting power at the input of the amplifier system 300, for example, using an external device (e.g., a signal generator, via a CMTS, a base station interface 104, etc.). The input power of the amplifier system 300 may be manipulated automatically, for example, by programmatically manipulating transmitter power of existing channels. Also, or alternatively, the input power of the amplifier system 300 may be manipulated automatically, for example, by programmatically adding additional power within a vacant or unused portion of a spectrum.

At step 515 of the method 500, input characteristics and/or output characteristics of the amplifier system 300 may be determined. Noise levels and/or power values for the input and/or output of the amplifier system 300 may be determined, for example, by measuring locally at test ports of the amplifier system 300. Noise levels and/or power values for the input and/or output of the amplifier system 300 may be determined, for example, at a location different from an endpoint device and/or terminal device (e.g., a CPE) using the endpoint device and/or terminal device's spectrum analysis tools (e.g., full band capture (FBC)). In addition to the spectrum of an amplifier system, SNR, power, and/or CNR may also be determined at a location different from the endpoint device and/or terminal device (e.g., a CPE). Noise power may be measured as SNR and/or CNR by observing signal power and the noise power in a vacant spectrum. Noise power may also be measured as a combination of MER, SNR, and/or received power, for example, if received from a demodulator. An amplifier system may be configured to allow test point attributes to be measured remotely via software from a push server 105 and/or an app sever 107.

At step 520 of the method 500, the amplifier system 300 may be characterized. The amplifier system 300 may be characterized, for example, based on noise levels (e.g., SNR). The SNR may remain constant as input power is changed. A SNR that remains unchanged with changing input power may indicate, for example, that the amplifier is in an AGC state. The SNR may change as input power is changed. A change in SNR with a change in input power may indicate, for example, that the amplifier system is in a nonlinear region. Alternatively, a change in SNR with a change in input power may indicate, for example, that the amplifier system 300 is in a constant gain state. The SNR may decrease asymmetrically as input power is increased in step 510, for example, if amplifier distortions are present a 1 dB of input Rx power may have no impact on output power and SNR and NPR may decrease by 3 dB because of a disproportionate amount of noise created by the non-linearity of the amplifier system 300.

Output power of the amplifier system 300 may change as input power is manipulated in step 510. Output power may increase as input power is increased, for example, if the amplifier system 300 is constant gain and additional power is added to a channel on the input. The increase in output power may lead to an increase in SNR. Alternatively, the amplifier system 300 may maintain a constant output level, and, thereby, a constant SNR. The amplifier system 300 may maintain a constant output level, for example, if the amplifier system 300 is in an automatic gain control (AGC) state.

The shape of the noise floor may characterize the amplifier system 300. The noise floor of an under-driven amplifier system may have a substantially or about uniform (e.g., flat) noise floor across the frequency spectrum, for example, because amplified noise, rather than distortion products, is the predominate contributor to the noise floor. A local range of a noise floor of a spectrum may be analyzed by fitting the data of the local range to linear, 2nd order, and/or higher order polynomials. The response may be fit to an NPR curve 450 and modeled as ax³+bx²+cx+d, for example, if the amplifier system is in the noise region 405 of the NPR curve 450, a will be small and the response curve will be dominated by the b and c terms; if the amplifier system is in the clipping region 420, a and b may dominate; and if in the intermodulation region b may dominate. The local range of the noise floor may be fit to a linear equation and linearity determined, for example, based on linear regression and the linear regression's coefficient of determination, r². The linearity of the local range of a noise floor may be based on r², for example, because r² may be interpreted as the likelihood that the observed variation in the noise floor is explained by a linear model. r² is a value that may range from 0 to 1, where 0 indicates that there is no correlation between noise power and a linear regression model and 1 indicates a perfect fit. Linearity may be determined by a minimum r² value. The local range of the noise floor may be determined to be linear for a range of r² values, for example, if r² is greater than 0.8. Additionally, noise floors that may be linearly increasing or decreasing may be differentiated from noise floors that may remain constant. The slope determined using a linear regression analysis may be used to determine the magnitude in change of a noise floor from a constant value.

The noise floor may be dominated by distortion products (e.g., distortion products are the predominate contributor to the noise floor) rather than amplified noise for an over-driven amplifier system 300. The noise floor of the spectrum of an over-driven amplifier system 300, for example, may have a parabolic (e.g., a hump shape) rather than a uniform (e.g., flat) noise floor across the frequency range. The over-driven amplifier may be determined, for example, based on the noise floor having an r² below (e.g., less than, lower than, etc.) a threshold and/or the local spectrum fit to a parabolic curve (e.g., a quadratic function).

For an under-driven amplifier system 300, a composite noise floor may be dominated by amplified noise rather than distortion products. The spectra of an under-driven amplifier system 300, for example, may have increased uniformity (e.g., flat) (e.g., as compared to over-driven amplifier circuits) noise floor across the frequency range. The under-driven amplifier may be determined, for example, based on the noise floor having an r² greater (e.g., more, higher, etc.) than a threshold value indicating the linearity of the local region.

Additional power may be added to and/or subtracted from the input power to an amplifier system 300 to verify where along the NPR curve 400 the amplifier system 300 sits. At step 525 of the method 500, it may be determined to manipulate additional power values. A determination to further manipulate input power values may be determined based on an SNR change. It may be determined to further manipulate the input power, for example, if, in step 520 of the method 500, it was determined that the SNR did not remain substantially constant as the input power was changed. Alternatively, it may be determined to not further manipulate the input power, for example, if, in step 520, it was determined that the SNR remained substantially constant as the input power was changed.

At step 530 of the method 500, a position along the NPR curve 400 for the amplifier system 300 may be determined. An amplifier system 300 may be determined to be on the left side (e.g., the noise region 405) of the NPR curve 400, for example, if the amplifier system 300 is constant gain and the output power and/or SNR (e.g., as determined in step 515) increase as the manipulated input power is increased (e.g., in step 510). It may also be determined that the amplifier system 300 is on the left side (e.g., the noise region 405) of the NPR curve 400, for example, if the amplifier system 300 is in an AGC state and the output power and/or SNR (e.g., as determined in step 515) are constant as the input power is manipulated (e.g., in step 510). Also, or alternatively, it may also be determined that the amplifier system 300 is on the right side of the NPR curve 400, for example, if the SNR decreases asymmetrically with an increase in input power.

At step 535 of the method 500, one or more system settings, other than gain control pilots (e.g., a reference frequencies, reference sideband frequency, pilot levels, etc.), of the amplifier system 300 may be changed to maintain stable system levels (e.g., noise power levels). Input power levels may be decreased, for example, to move the amplifier system from the intermodulation region 415 to the noise region 405 of the NPR curve 400. Power levels associated with the amplifier system may be changed. Power transmitted by an amplifier preceding the amplifier system being tested may be changed. The power from a CMTS and/or small cell interface 104 may be changed. Also, or alternatively, the amount of spectrum used by the CMTS may be changed. Additionally, receive power in the CMTS may be changed while changing the transmit power from a modem 110. Settings of an attenuator at the input (e.g., first pad 610), an attenuator at the output (e.g., third pad 637), and/or an interstate attenuator (e.g., second pad 615) may be changed. Technicians may do set attenuators manually at the amplifier system. Alternatively, an amplifier may be configured with a programmable attenuator and the entire system may be configured remotely in order to be fully automated.

The amplifier system 300 may comprise an AGC system. The AGC system may maintain a stable, suitable signal amplitude at the output of the AGC system despite varying input signal amplitudes. Analysis and optimization of the gain control pilots of the AGC system of the amplifier system 300 may also be performed, for example, if the amplifier system 300 comprises an AGC system. FIG. 5B is a flow chart showing an example method 550 for automatic analysis and optimization of the internal gain control circuits of the amplifier system 300 by separately manipulating the gain control pilots.

At step 555 of the method 550, the initial input and/or output characteristics of an amplifier system 300 may be determined. At step 560, gain control pilots of the amplifier system 300 may be manipulated while other system settings of the amplifier system 300 are maintained at constant levels. System settings that may be changed comprise gain, slope/tilt, equalization, automatic gain control (AGC), padding and/or attenuation may adjusted. Some system settings may also be specific to a gain stage and/or a direction (e.g., upstream vs downstream, forward or return, etc.).

At step 565 of the method 550, a system response of the amplifier system 300 may be determined. The system response may be measured and analyzed, for example, as the pilot carrier out of a node is changed (e.g., raised and/or lowered) while the remaining spectrum is held constant. The performance of the AGC system of the amplifier system 300 may be determined, including cascading of one or more amplifiers, based on the determined system response.

At step 570 of the method 550, performance of the AGC system may be characterized, for example, by determining an AGC reserve and/or a dynamic range capability. The AGC reserve provides capacity to increase or decrease operating levels of the AGC output, and the dynamic range capability describes the range of available output signal. AGC reserve may be measured, for example, by raising and/or lowering power output versus power input on the AGC. A dynamic range capability of the AGC system may be tested, for example, against a known reserve (e.g., a reserve on a 1.2 GHz broadband line extender (BLE120) may be about 3-4 dB).

At step 575 of the method 550, it may be determined, for example, whether the gain control pilots are to continue to be manipulated. AGC reserve may be measured, for example, by raising and lowering the power output versus the input on the AGC. A determination to further manipulate the power output versus the input on the AGC may be based on the output signal and/or SNR. It may be determined to further manipulate the power output versus the input, for example, if the output remains constant. Alternatively, it may be determined to not further manipulate the power output versus the input, for example, if the output does not remain constant. The dynamic range capability of the amplifier system 300 may be determined, for example, based on the AGC reserve. An AGC may be configured to keep operation of the amplifier system 300 near, but left of, the peak NPR 410 of the NPR curve 400. An amplifier system 300 may have a maximized AGC gain, for example, if the network is aligned or has damage, and the amplifier system may be in the noise region 405. To detect this case, an amplifier system 300 may be optimized in cascade, and/or CMTS or modem 110 transmit power levels may be changed. An amplifier system 300 may be configured to with programmable controls that may allow the amplifier system 300 to be configured collectively.

One or more of the steps described in example methods 500 and/or 550 may be automated for the ongoing analysis and/or maintenance of RF amplifiers within a communications network. The methods may be performed, for example, on a schedule that may comprise analyzing and/or maintaining the RF amplifiers (e.g., on a cyclical schedule). The methods may be performed on a schedule, for example, to collect amplifier system 300 data over a period of time to analyze trends. Trends may be determined to anticipate and/or prevent likely issues. Automatic detection and analysis may function continuously and/or proactively to adapt to network changes rather than merely responding to system failures. Moreover, one or more of the steps described in example methods 500 and/or 505 may enable the automatic configuration and balancing of amplifiers (e.g., “smart amplifiers”), for example, in the forthcoming DOCSIS 4.0 full-duplex networks. Automated optimization of a system of amplifiers may ensure that the system of amplifiers may operate with increased efficiency and may reduce costs associated with existing practices.

Input power of an amplifier system may be manipulated manually (e.g., at the location of the amplifier system) and input and/or output signals (e.g., at input and/or output test points) of the amplifier system measured at the location of the amplifier system or at a location different from the amplifier system. An amplifier system may comprise one or more amplifier systems 300 as described herein in various configurations, for example, the amplifier system 600 of FIG. 6A may comprise two of amplifier system 300 in series. FIG. 6A shows an example of a process for manual input power manipulation of an amplifier system 600. Specifically, FIG. 6A shows an example of a process for manipulating input power to an amplifier system 600 using a device 605 (e.g., an external device, a signal generator, a CMTS, a distributed access architecture (DAA) node, an amplifier in a cascade before the amplifier system 600 or first amplifier 630, etc.) and measuring the response at the input (e.g., an input test point 620) and/or output (e.g., an output test point 625). The amplifier system 600 may comprise one or more amplifiers (e.g., a first amplifier 630 and a second amplifier 635), one or more interstage pads (e.g., a first pad 610 and a second pad 615), one or more test ports (e.g., the input test port 620 and/or the output test port 625), and one or more connections for an external device 605 to inject power at the input of an amplifier system 600. The one or more amplifiers (e.g., the first amplifier 630 and the second amplifier 635) may comprise one or more amplifier systems 300 as described herein. The one or more pads (e.g., a pre-attenuation device (PAD)) may be used, for example, to reduce signal levels. The one or more pads may be used, for example, to balance the amplifier system 600 by adjusting signal levels. Incorrect padding may lead to a reduced SNR, for example, by over attenuating the signal. Incorrect padding may happen if padding is incorrectly configured in an amplifier system 600. An amplifier system 600 may be a part of a larger amplifier system. An amplifier system may comprise cascades of amplifiers comprising one or more amplifiers in cascade. An amplifier system may comprise one or more hybrid fiber-coaxial (HFC) amplifiers, capable of amplifying signals in both directions.

Input characteristics of the amplifier system 600 may be determined (e.g., received, tested, acquired, etc.) at an input test port 620. Output characteristics of the amplifier system 600 may be determined (e.g., received, tested, acquired, etc.) at an output test port 625. The input characteristics and/or output characteristics of the amplifier system 600 may be determined remotely. The input and/or output characteristics of the amplifier system 600 may comprise power values and/or noise levels. The input characteristics and/or output characteristics may be measured at one or more points before, during, and/or after the input power is manipulated. The input characteristics and/or the output characteristics may be measured, for example, before the device 605 injects power into the input of the amplifier system 600. The input characteristics and/or the output characteristics may be measured at one or more points, for example, as the device 605 injects power into the input of the amplifier system 600. The device may be a signal generator operated by a technician.

FIG. 6B shows an example of two endpoint device and/or a terminal device spectra (e.g., a CPE). The endpoint device and/or a terminal device (e.g., CPE) spectra may be measured at the location of the endpoint device and/or a terminal device or at a location that may be different from the endpoint device and/or a terminal device. An amplifier system may be configured to be remotely measured, for example, to provide similar data as a spectrum analyzer at the amplifier system 600. Specifically, FIG. 6B shows an example of two CPE spectra comprising an initial state spectrum 650a and a final state spectrum 650b. The initial state spectrum 650a and the final state spectrum 650b may be associated with the amplifier system 600 having a first pad 610 and a second pad 615 having different paddings (e.g., pad values). The initial state spectrum 650a may be the spectrum associated with the amplifier system 600 that may have the first pad 610, for example, with an initial padding value 612a and the second pad 615, for example, with an initial value 617a. The final state spectrum 650b may be the spectrum associated with the amplifier system 600 that may have the first pad 610, for example, with a final padding value 612b and the second pad 615, for example, with a final value 617b. As an example, initial state of the amplifier system 600 associated with the initial state spectrum 650a may have interstage padding that leads to the amplifier system 600 being in the clipping region 420 of the NPR curve 400, while the final state spectrum 650b may have interstage padding that leads to the amplifier system 600 being in the noise region 405 of the NPR curve 400. For example, the initial state padding 612a of the first pad 610 and the initial state padding 617a of the second pad 615 may be, for example, 0 dB and 12 dB respectively, and the final state padding 612b of the first pad and the final state padding 617b of the second pad 615 may be, for example, 12 dB and 0 dB respectively. The initial state dn 670a, for example, determined based on the initial state lfnf 660a and the initial state hfnf 665a, may be greater than the final state dn 670b, for example, determined based on the final state lfnf 660b and the final state hfnf 665b. This provides for the capability of an endpoint device and/or a terminal device (e.g., a CPE, a modem 110 as described herein in FIG. 1, etc.) to be analyzed and analysis used to optimize the amplifier in the field.

FIG. 6C shows an example of determined positions on an NPR curve 450. Specifically, FIG. 6C shows an example of determined positions of the initial state 680a (e.g., the first pad 610 being 0 dB and the second pad 615 being 12 dB) of the amplifier system 600 and the final state 680 b (e.g., the first pad 610 being 12 dB and the second pad 615 being 0 dB) of the amplifier system 600 on an NPR curve 450. The initial state may correspond to the initial state 680a on the NPR curve 450 based on the initial state dn 670a and an initial state injected TCP, and the final state may correspond to the final state point 680b on the NPR curve 450 based on the final state dn 670b and the final state injected TCP. The amplifier system 600 went from a state where the non-linearity of the amplifier system 600 may cause the SNR to decrease with increasing input power (e.g., the clipping region 420 of the NPR curve 400) to a state where the amplifier is linear and the SNR increases with increasing input power (e.g., the noise region 405 of the NPR curve 400) by altering the interstage padding of a first pad 610 and a second pad 615 of the amplifier system 600, for example, based on the example endpoint device and/or terminal device (e.g., CPE) spectra 650a and 650b of the initial state and the final state of the amplifier system 600.

Also, or alternatively, one or more steps of example methods 500 and/or 550 may be further automated by, for example, manipulating the power to the amplifier system from a location different from the amplifier system. The input power may be manipulated, for example, by manipulating (e.g., programmatically) the transmitter power of one or more existing channels (e.g., a single channel, a channel block, and/or an entire occupied spectrum) in an amplifier system, or alternatively, the input power may be manipulated, for example, by adding (e.g., programmatically) power within a vacant and/or unused portion of a spectrum (e.g., a ghost spectrum). Such automated optimization may comprise, for example, remotely receiving endpoint device and/or a terminal device (e.g., CPE) spectrum data, and/or may comprise analyzing the endpoint device and/or the terminal device (e.g., CPE) spectrum data from a location different from the endpoint device and/or a terminal device (e.g., CPE).

FIG. 7A shows an example of automated input power manipulation and analysis of an amplifier system 700. Specifically, FIG. 7A shows an example of automated input power manipulation and analysis of an amplifier system 700 that may be performed from a location different from the amplifier system 700. The amplifier system 700 may comprise one or more amplifier system(s) 300 in various configurations. The amplifier system 700 may comprise, for example, two of amplifier system 300 in series. The amplifier system 700 may comprise one or more amplifiers (e.g., a first amplifier 710 and/or a second amplifier 720). The amplifier system 700 may comprise one or more test points and/or points were spectra data may be determined (e.g., input test point 705 and/or output test point 715). The one or more test points may comprise a first test point 705 (e.g., input) and/or a second test point 715 (e.g., output). An endpoint device and/or a terminal device (e.g., CPE) spectrum may be determined indicating a change in output power resulting from a change in input power. The input power may be manipulated by, for example, supplying power to an unused channel, for example, remotely, via a CMTS and/or an interface 104, locally via a tone generator or signal meter, and/or automatically via a smart amplifier upstream or downstream in a cascade.

A endpoint device and/or a terminal device (e.g., CPE) spectrum may be measured, for example, as SNR and/or CNR by observing signal power and noise power in a vacant spectrum. A modulation error ratio (MER) may be a measurement of the quality of a received signal. MER may be used to evaluate performance of an amplifier system 700. MER may be the ratio of average signal power to average error power. A receive modulation error ratio (RxMER) (i.e., the receiver side MER) may be received for each subcarrier and/or as an average of all subcarriers. A endpoint device and/or a terminal device (e.g., CPE) spectrum taken while power is applied to an unused channel may indicate where along the NPR curve 450 the amplifier system 700 is located. The SNR may increase with increasing input power, for example, as the output signal power increases while noise power remains constant with the increasing input power, if the amplifier system 700 is located in the noise region 405 of the NPR curve. The SNR may remain constant with increasing input power, for example, because the output power in the dynamic range 425 of the NPR curve 400 may be maintained at a constant level if the amplifier system 700 is in an AGC state. The amplifier system 700 may be determined to be in a non-linear region (e.g., the clipping region 420) of the NPR curve 400, for example, if the SNR is found to decrease non-linearly (e.g., at a rate higher than 1:1) with increasing input power. A decrease of NPR or MER of 3 dB may be measured, for example, for an input power increase of 1 dB. This type of behavior may be seen as the output power remaining constant, but the noise floor increasing.

FIG. 7B shows an example of a first endpoint device and/or a terminal device (e.g., a CPE) spectrum of a first amplifier system. Specifically, FIG. 7B shows an example of a first endpoint device and/or a terminal device (e.g., CPE) spectrum 730 of a first configuration of the amplifier system 700. An input power of a ghost channel of the unused spectrum may be manipulated. The total composite input power, for example, may be increased by 1 dBmV. A TCP increase of 1 dBmV may be determined by an application server 107, for example, based on calculations of total power in the spectrum of the FBC and adding additional spectrum until the total power across the composite spectrum is 1 dB higher.

A dn of the first configuration of the amplifier system 700 may be determined, for example, based on the difference between the lfnf 735 and the hfnf 745. The first configuration of the amplifier system 700 may be determined to be at a position 740 on an NPR curve 450, for example, based on a small increase in TCP (e.g., 1 dB mV) resulting in small increase in SNR (e.g., of the order of the TCP increase). A small increase in the linear region (e.g., region 405 of NPR curve 450) may be seen as a 1 dB increase in power output and/or a 1 dB increase of MER, for example, for a 1 dBmV increase in the input power. A small increase in regions 410 and/or 415 of NPR curve 400 may be seen as less than a 1 dB increase in power output and a MER that remains nearly constant or increases slightly, for example, for a 1 dBmV increase in the input power.

A small increase in region 420 and/or 425 of NPR curve 400 may be seen as no increase or negative change in output power and/or a 3 dB decrease in MER, for example, if Rx power is increased by 1 dB in Rx power. The RxMER of the first configuration of the amplifier system 700 corresponding to the first spectra may be −0, for example, based on the RxMER received. Noise of the amplifier system 700 may be determined based on the RxMER. RxMER may be defined essentially as the signal power divided by the noise power, for example, and if we know the signal power the MER may be determined. Also as described above the MER increasing or decreasing may assist in determining where on the NPR curve 400 an amplifier system is. The RxMER may be obtained, in the DS, by querying the modems 110. The RxMER may be returned to push server 105 and an app server 107. The RxMER, in the upstream, may be obtained from the CMTS and/or a base station via the same servers. Manipulating an amplifier system may affect the RxMER.

Amplifiers may be setup incorrectly (e.g., by a technician). A network between amplifiers may degrade over time and the amplifiers may move left along the NPR curve 400. Once a network may later be repaired, an amplifier may be shifted right, towards or into the clipping region 420 on the NPR curve 400, for example, if the amplifier is not readjusted to account for the changes in the network. Temperature changes may cause changes (e.g., an increase or a decrease) in attenuation between amplifiers that may change the position of the amplifier on the NPR curve 400. An amplifier may be found to be in a non-linear region of the NPR curve, for example, if the amplifier was setup during weather extremes may and after the weather moderates. Additionally, a single amplifier improperly adjusted in a cascade amplifier system may cause amplifiers above and/or below the amplifier to be out of desired operating ranges, for example, in the cascade amplifier system. Moreover, an amplifier may be affected by noise ingress, for example, if noise power into the network is high.

FIG. 7C shows an example of a second endpoint device and/or a terminal device (e.g., a CPE) spectrum of a second amplifier system. Specifically, FIG. 7C shows an example of a second endpoint device and/or a terminal device (e.g., CPE) spectrum 760 of a second configuration of the amplifier system 700. The second endpoint device and/or a terminal device (e.g., CPE) spectrum may be measured, for example, as the TCP input is increased (e.g., by 1 dBmV). A dn of the second configuration of the amplifier system 700 may be determined, for example, based on the difference between the lfnf 735 and the hfnf 765. The second configuration of the amplifier system 700 may be determined to be at a position 770 on the NPR curve 450, for example, based on a small increase in TCP (e.g., 1 dBmV) resulting in a decrease in SNR. The RxMER of the second configuration of the amplifier system 700 corresponding to the second spectra may be, for example, about −3, for example, based on the RxMER received.

FIG. 8A shows an example of automated input power manipulation and analysis of an amplifier system 800. Specifically, FIG. 8A shows an example of automated input power manipulation and analysis of an amplifier system 800 that may be performed from a location different from the amplifier system. The amplifier system 800 may comprise one or more amplifier system 300 in various configuration. The amplifier system 800 may comprise one or more amplifiers (e.g., The amplifier system 800 may comprise one or more test points. The one or more test points may comprise a first test point 805 (e.g., input) and/or a second test point 815 (e.g., output). The amplifier system 800 may further comprise one or more amplifiers (e.g., a first amplifier 810 and/or a second amplifier 820). The one or more amplifiers may be amplifier system(s) 300. Referring to FIGS. 8A, 8B, and 8C, the input power may be manipulated by increasing launch power of the existing spectrum.

FIG. 8B shows an example of a first endpoint device and/or a terminal device (e.g., a CPE) spectrum of a first amplifier system. Specifically, FIG. 8B shows an example of a first endpoint device and/or a terminal device (e.g., CPE) spectrum 830 of a first configuration of the amplifier system 800. An input power to the amplifier system 800 may be manipulated by, for example, increasing launch power of existing spectra. The total composite input power may be increased (e.g., by 1 dBmV). A dn of the first configuration of the amplifier system 800 may be determined, for example, based on the difference between the lfnf 835 and the hfnf 845. The first configuration of the amplifier system 800 may be determined to be at a position 840 on the NPR curve 450, for example, based on a small increase in TCP (e.g., 1 dBmV) resulting in a small increase in SNR (e.g., a change of the order of the TCP increase). The RxMER of the amplifier system 800 corresponding to the first spectra may be, for example, about −0, for example, based on the RxMER received. Noise of the amplifier system 800 may be determined based on the RxMER.

FIG. 8C shows an example of a second endpoint device and/or a terminal device spectrum of a second amplifier system. Specifically, FIG. 8C shows an example of a second endpoint device and/or a terminal device (e.g., CPE) spectrum 860 of a second configuration of the amplifier system 800. The second endpoint device and/or a terminal device (e.g., CPE) spectrum 860 may be measured, for example, as the TCP input is increased (e.g., by 1 dBmV). A dn of the second configuration of the amplifier system 700 may be determined, for example, based on the difference between the lfnf 835 and the hfnf 865. The second configuration of the amplifier system 800 may be determined to be at a position 870 on the NPR curve 450, for example, based on a small increase in TCP (e.g., 1 dBmV) resulting in a decrease in SNR (e.g., of the order of the TCP increase). The RxMER of the second configuration of the amplifier system 800 corresponding to the second spectra may be, for example, about −3, for example, based on the RxMER received.

Although examples are described above, features and/or steps of those examples may be combined, divided, omitted, rearranged, revised, and/or augmented in any desired manner. Various alterations, modifications, and improvements will readily occur to those skilled in the art. Such alterations, modifications, and improvements are intended to be part of this description, though not expressly stated herein, and are intended to be within the spirit and scope of the disclosure. Accordingly, the foregoing description is by way of example only, and is not limiting.

We claim:

1. A method, comprising:
sending, to a first device comprising one or more amplifiers, a first indication to:
change input power, from an initial input power to a final input power, of one or more of the one or more amplifiers; and
measure one or more parameters comprising noise of the one or more amplifiers;
sending to the first device a second indication comprising one or more configuration parameter changes of one or more configuration parameters of the one or more amplifiers, wherein the one or more configuration parameter changes is based on the one or more parameters comprising noise; and
causing, based on the second indication, the one or more configuration parameters of the one or more amplifiers to change.

2. The method of claim 1, further comprising sending to a second device a message comprising measurements of the one or more parameters comprising noise.

3. The method of claim 1, further comprising:
determining an input power change, wherein the input power change is a difference between the initial input power and the final input power;
comparing the input power change to one or both of:
an output power change, wherein the output power change is a difference between an initial output power and a final output power, or
a change in a ratio of signal and noise powers after the input power change; and
wherein the one or more configuration parameter changes are based on the comparing.

4. The method of claim 1, wherein the one or more amplifiers are part of:
a complete amplifier assembly; or
an embedded amplifier circuit.

5. The method of claim 1, wherein the one or more configuration parameters comprise amplifier pads and equalizer settings.

6. The method of claim 1, further comprising determining a position of one or more of the one or more amplifiers along a noise power ratio (NPR) curve based on the change in input power and the one or more parameters comprising noise.

7. The method of claim 1, wherein the one or more parameters comprising noise of the one or more amplifiers comprise one or more of:
a modulation error ration (MER);
a signal-to-noise ratio (SNR);
one or more input powers;
one or more output powers;
one or more input noise powers;
one or more output noise powers; or
one or more endpoint device spectra captures.

8. The method of claim 1, further comprising:
determining a linearity of a noise floor based on consumer premises equipment (CPE) spectra;
determining a distortion noise (dn) based on a difference between a low frequency noise floor and a high frequency noise floor based on the CPE spectra; and
wherein the one or more configuration parameter changes is based on one or both of the linearity of the noise floor or the dn.

9. A method, comprising:
receiving, by a device comprising an amplifier system, an indication to change power at an input of the amplifier system;
changing the input power of the amplifier system from an initial input power to a final input power;
measuring one or more amplifier system input values comprising an input noise profile and one or more amplifier system output values comprising an output noise profile; and
causing an adjustment to a configuration setting of the amplifier system based on one or more of the input noise profile and the output noise profile.

10. The method of claim 9, wherein the amplifier system comprises one or more of an individual amplifier, a complete amplifier assembly, an embedded amplifier circuit, and a subsystem of amplifiers within the amplifier system.

11. The method of claim 9, wherein the one or more of the input noise profile and the output noise profile comprise:
an input noise level;
an input signal-to-noise ratio (SNR);
an input carrier-to-noise ratio (CNR)
an input modulation error ration (MER);
an output noise level;
an output SNR;
an output CNR; and
an output MER.

12. The method of claim 9, further comprising determining one or more consumer premises equipment (CPE) spectra; and
wherein the causing an adjustment to a configuration setting of the amplifier system is further based on the CPE spectra.

13. The method of claim 9, further comprising sending the one or more system input values and one or more system output values.

14. A method, comprising:
causing a change in transmitting power of one or more channels of an amplifier system comprising one or more amplifiers;
causing a measuring of one or more channel characteristics comprising a noise profile of at least one of the one or more channels;
receiving the measurements of the one or more channel characteristics; and
characterizing a state of the amplifier system based on the measurements of the one or more channel characteristics.

15. The method of claim 14, further comprising causing a configuration parameter of the amplifier system to be adjusted based on the noise profile.

16. The method of claim 14, wherein at least one of the causing the change in transmitting power and measuring the change in one or more channel characteristics is from a location different from the amplifier system.

17. The method of claim 14, wherein the one or more channel characteristics comprise one or more of:
a signal-to-noise ratio (SNR);
a carrier-to-noise ratio (CNR);
a modulation error ratio (MER);
an input noise power; or
an output noise power.

18. The method of claim 14, wherein the causing a change in transmitting power is an external device.

19. The method of claim 14, wherein one or more of the one or more channels are vacant channels.

20. The method of claim 14, wherein one or more of the one or more channels are existing channels.
